(19) United States
(12) Patent Application Publication
(10) Pub. No.: US 2006/0281221 A1
(43) Pub. Date: Dec. 14, 2006

(54) Enhanced routing grid system and method

(76) Inventors: Sharad Mehrotra, Cedar Park, TX (US); Parsotam T. Patel, Austin, TX (US); Joe T. Rahmeh, Austin, TX (US); Jeanette N. Sutherland, Cedar Park, TX (US)

Correspondence Address: J. SCOTT DENKO, ANDREWS & KURTH LLP, 111 CONGRESS AVE., SUITE 1700, AUSTIN, TX, 78701, US

(21) Appl. No.: 11/148,911

(22) Filed: Jun. 9, 2005

(51) Int. Cl. H01L 21/00

(52) U.S. Cl. 438/107

(57) ABSTRACT

Routing systems and methods are provided having various strategies for optimizing and evaluating possible routes for netlist connections. In one embodiment, a data structure or matrix provides cost related data weighted to evaluate the impact proposed a connection or segment will have upon an attribute of interest such as, for example, speed, manufacturability or noise tolerance. This cost information can be related to terrain costs as well as shape costs to provide multidimensional cost information for connections. Processing such higher information cost data is made more efficient with an additive process that is less demanding than a computationally intensive iterative multiplication process. Various methods are also disclosed for shifting and adjusting routing grids to improve use of available space or reduce run time in routing. In another embodiment, a parallel processing scheme is used to process multiple regions on multiple processors simultaneously without creating conflicts, that could arise, for example, when two processors try to route a trace on the same gridpoint.

### TECHNICAL FIELD

The present invention relates to systems and methods for routing traces or wires for an integrated circuit or other electronic design.

### BACKGROUND

A layout is a map of electrical connections on various layers in a semiconductor integrated circuit. Computer-driven routing systems are often used to build layouts to articulate designs to be expressed in an integrated circuit. Such systems typically use a netlist which is a description of required connections between terminals, and create a routed design or layout to make such required connections.

Typically such computer driven routing systems are grid based systems that route traces on a routing grid. Some systems also employ a gridless routing scheme, in which routing shapes may be placed at very precise locations.

In such a conventional grid based routing system, each layer of an integrated circuit chip is represented as a routing grid. The grids for the various layers together form a 3D routing grid. A typical integrated circuit will have at least one semiconductor layer and three wiring layers. The three wiring layers are sometimes referred to as HVH (horizontal-vertical-horizontal). ‘Horizontal’ or ‘vertical’ indicates that the layer is generally used to make traces that traverse in that direction. Vias interconnect adjacent layers.

To perform routing, the router must first receive chip technology data including various rules such as geometric rules that describe parameters such as the characteristics of layers on which rectangles representing wires can be generated, the minimum allowed width of any part of a trace, and the minimum allowed separation between traces. Typically, a router includes a global routing step for allocating groups of nets to be routed through corresponding general routing areas.

A number of conventions are employed in typical routing systems and methods. For example, the common “centerline convention” places the center of traces on the routing grid gridlines. When a net is routed, for various reasons, the trace must be distanced from existing obstacles or structures, such as, for example, other traces, including vias, and pins of other nets that have been previously routed on the grid.

As integrated circuits employ smaller sizes such as, for example, submicron-sized designs, the congestion of traces in a circuit design tends to increase. Further, modern designs tend to have wires or traces having different and non-uniform size and spacing. Typical grid-based systems may not efficiently handle such increased congestion and size variation. The increased congestion and size variation place greater constraints on the routing grid pitch employed in a particular region.

One common approach to such increased congestion and size variation is to reduce the pitch of the routing grid to allow more precise placement. Such a scheme causes, however, significant increase in the number of grid points and a corresponding increase in search time.

Another approach is to use a gridless or shape-based routing system. Such a system tracks traces and other obstacles based upon their relative locations. Shape-based systems are typically not limited to a predefined routing grid. The systems are, however, typically slow and complex.

In the IC industry, different objectives for a design are served by different design features. For example, design attributes that improve manufacturability may not so readily serve the interests of feature density just as attributes that serve reduced delay may not so readily serve other interests. The trade offs between manufacturability, reduced delay and timing sensitivity have typically been allocated with methods that are less than systematic and efficient.

What is needed, therefore, are routing techniques that provide speed similar to a grid-based system, but accuracy and flexibility that compares favorably with a shape-based system but which provide efficient management of the trade offs between manufacturability, timing, and reduced delay.

### SUMMARY

Routing systems and methods are provided having various strategies for optimizing and evaluating possible routes for netlist connections. In one embodiment, a data structure or matrix provides cost-related data weighted to evaluate a connection or segment of a connection based upon an attribute of interest such as, for example, reduced delay (i.e., impact on speed), manufacturability or noise tolerance. In some embodiments, the attribute-weighted cost information includes cost information related to neighborhood or terrain costs and intrinsic or shape costs to provide multidimensional cost information for connections. In some embodiments, the processing of such higher .information cost data is made more efficient with an additive process that is less demanding than a computationally intensive iterative multiplication process.

In another embodiment, certain traces are offset from the routing grid to help provide efficient grid usage. Other embodiments have an enhanced routing grid capability that provide those parts of a dense routing grid employed to efficiently route off main grid sites or pins, for example. Various methods are also disclosed for shifting and adjusting routing grids to improve use of available space or reduce run time in routing.

In another embodiment, a parallel processing scheme is used to process multiple regions on multiple processors simultaneously without creating conflicts, that could arise, for example, when two processors try to route a trace on the same gridpoint.

### BRIEF DESCRIPTION OF THE DRAWINGS

FIG. 1A depicts a prior art grid labeling scheme.

FIG. 1B depicts a finer granularity grid labeling strategy that weights the cost of a connection or structure.

FIG. 2 depicts a method of enhancing grid precision and usability by offsetting traces from gridpoints.

FIG. 3A depicts a step in using a subgrid according to one embodiment of the present invention.

FIG. 3B depicts a reduced subgrid according to an embodiment of the present invention.

FIG. 4 depicts a route for a connection from a source to a target as a series of steps.

FIG. 5 depicts a routing strategy according to one preferred embodiment of the present invention.

FIG. 6A and FIG. 6B illustrate a sparse grid flyover technique according to one embodiment of the present invention.

FIG. 7 depicts a global routing scheme using sparse routing grids according to one embodiment of the present invention.

FIG. 8 depicts a flow chart of a global routing scheme using sparse routing grids.

FIG. 9 illustrates a parallel processing routing scheme according to one embodiment of the present invention.

FIG. 10 depicts a flow chart of a parallel processing routing scheme according to one embodiment of the present invention.

FIG. 11 illustrates a parallel processing routine scheme according to another embodiment of the present invention.

FIG. 12 illustrates a global routing function employed in combination with a parallel processing function in a scheme according to one embodiment of the present invention.

FIG. 13 depicts a flow chart of a global routing function employed in combination with a parallel processing function according to one embodiment of the present invention.

FIG. 14 illustrates a grid adjustment scheme according to one embodiment of the present invention.

FIG. 15 and FIG. 16 illustrate a trace adjustment scheme according to one embodiment of the present invention.

### DETAILED DESCRIPTION OF PREFERRED EMBODIMENTS

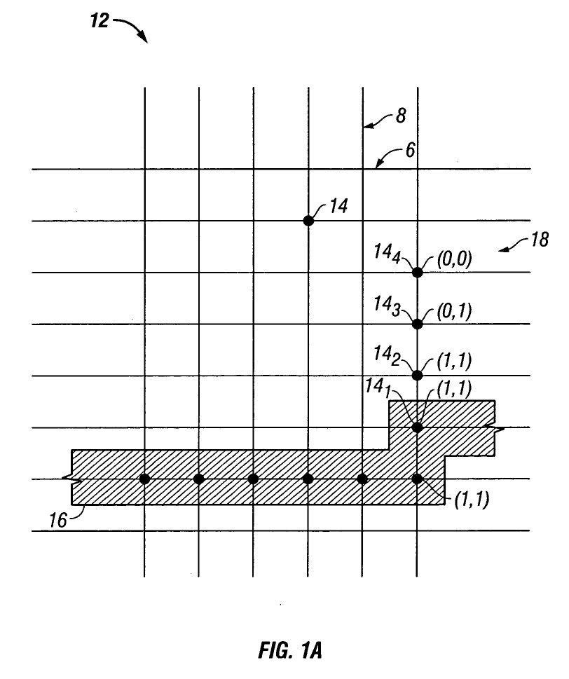

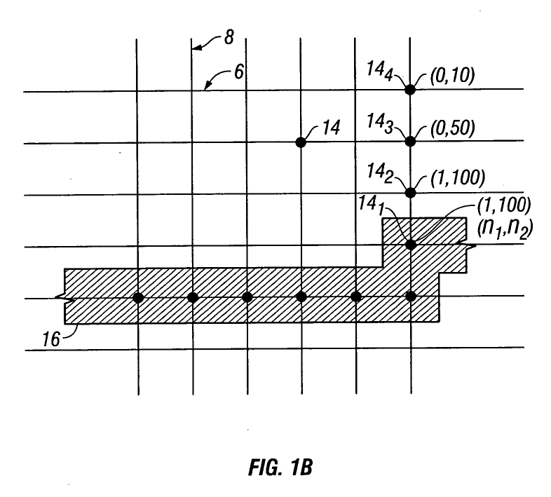

FIG. 1A depicts a prior art grid labeling scheme. Grid 12 is a routing grid upon which traces are routed to make connections between desired locations in the grid area, such as, for example, gridpoints 14. The depicted grid 12 is formed of horizontal gridlines 6 and vertical gridlines 8 which. intersect to create gridpoints 14.

Typically, routing a path or trace 16 requires routing path segments between certain gridpoints or pins. A search algorithm searches the grid to find an unblocked route through which to route trace 16. Once a route is. found, many routing systems record the route using a one-bit scheme in which “1” represents that a gridpoint 14 is blocked and “0” represents that a gridpoint 14 is open for use (unblocked). More sophisticated systems employ a two-bit matrix typically stored as a data structure 18 to represent the status of each gridpoint 14. Such a scheme enables matrix or data structure 18 to contain blocking information for more than one type of trace 16. In FIG. 1, the data structures 18 have two bits, the first or left-hand-depicted bit representing the status of each respective gridpoint 14 as being blocked or unblocked for a single-wide trace 16 while the second or right-hand depicted bit represents the status of each respective gridpoint as blocked or unblocked for use by a double-wide trace.

One embodiment of the present invention employs data structures that provide a deeper information related to a proposed route for a connection. Rather than bits indicative of one of two states (i.e., blocked/unblocked), the data structures or matrices 18 of a preferred embodiment express values representative of the impact upon selected attributes of interest such as, for example, reduced delay, noise tolerance, or manufacturability that result from routing the path or trace through a segment of the path bounded by a particular grid vertex with which the matrix or data structure has been associated. Although any number of values can be expressed by the cost matrix 18 in preferred embodiments, preferably, at least two matrix values are expressed by the cost matrix or data structure 18, each of the two values taking on one of at least three possible range values to convey more than a binary unblocked/blocked evaluation of the degree of impact that would impinge upon a selected attribute of interest by incorporation of the selected segment into a possible path for the proposed netlist connection. Typically, one of the range values available for expression by a matrix value of data structure 18 represents a prohibition on use of that segment for the proposed path with a proposed shape.

As shown in FIG. 1B, in the depicted embodiment, gridpoint 14₁ is shown having a data structure 18 that expresses two matrix values (n₁, n₂). The n₁, matrix value has taken on the range value 1 and the n₂ matrix value has taken on the range value 100. Thus, data structure or matrix 18 contains (1, 100), which indicates the associated gridpoint is blocked for use by a single-wide trace and a double-wide trace because for the first matrix value n₁, a “1” range value indicates complete prohibition on use by a single wide trace and for the second matrix value n₂, a “100” range value indicates complete prohibition on use by a double wide trace. The use of 100 in the n₂ position of the (n₁, n₂) matrix indicates a maximal blockage and corresponds to earlier systems that expressed that condition with a “1”. Such disability results, in this example, from the expression of depicted trace 16 along a route that already includes gridpoint 14₁.

When complete prohibition (blockage) is indicated by more than a “1” range value for a matrix value (n₁, n₂, * * *nₙ), in preferred embodiments, that typically means that other range values are available for that matrix value to express a degree of impact upon an attribute of interest other or less than complete blockage for a proposed shape. For example, where the range value 100 indicates blockage for the matrix value n2, there is typically available at least one range value more than “0” and less than “100” for that matrix value. Thus, the matrix value can take one of at least three different range values, at a minimum. When larger range values such as “100” are employed, in a typical preferred embodiment, there will be many range values available to allow a more continuum-like indication of impact upon an attribute of interest arising from use of that proposed segment or path.

Gridpoint 14₂ is also depicted as being entirely unavailable for both a single-wide and a double-wide trace. This is expressed by the respective matrix value range values (1,100) for matrix 18. This is because gridpoint 142 is within the design rule keepout or spacing requirement for the depicted trace 16. The spacing requirement is typically determined by desired electrical properties of traces 16. For example, if the depicted trace 16 is 100 nm wide, the design rules may specify a spacing requirement that it be 100 nm from any neighboring trace. Suppose, for example, that the depicted gridlines are arranged to form a 100 nm pitch grid. In such a case, gridpoint 142 would be within 100 nm of trace 16, and is, therefore, blocked by the spacing requirement or spacing zone of trace 16. Gridpoint 14₂ is shown blocked for both single-wide and double-wide traces 16, as indicated by (1, 100).

The next gridpoint 143 is shown as having data structure or matrix 18 containing (0, 50). Such range values indicate, in this example embodiment, that gridpoint 14₃ is unblocked for use by a single-wide trace, and may, if the cost is acceptable, be employed for use with a double-wide trace. The indication of a relative cost of 50 in the n2 position of the cost matrix (n1, n2) indicates that, although it is not absolutely prohibited, use of a double wide trace at 14₃ will come with some impact. The character of that impact is determined by the weighting given to that site by an optimization tool.

The optimization tool is directed to assign a cost for particular sites or vertices 14ₙ depending upon the relative values placed upon the attributes of interest such as manufacturability, reduced delay, and noise tolerance, for example. Preferably, when absolutely prohibited by prior use at that layer or the design rules, the maximum of the costing continuum of the matrix will be indicated. In this example, that number is 100. The number used to indicate complete prohibition is arbitrary, but expanding the range from 1 to 100 allows a finer gradation of cost to allow finer evaluation of attributes of interest such as reduced delay, noise tolerance or manufacturability, for example. Those of skill will note that other attributes of interest may be woven into the cost weighting, but reduced delay, noise, and manufacturability are the principal attributes of interest. The output of the optimization tool then becomes a label for a particular locus of the grid or a pin and that label is employed to find lower cost routes for particular connections.

The next gridpoint 14₄ is shown as having a cost matrix of (0, 10), indicating it is unblocked for use by both single-wide and has some, but minimal cost for use with double-wide traces. If a double-wide trace were to be routed along gridpoint 14₄, it would not overlap or violate the spacing requirement of the depicted trace 16. Also, the depicted trace 16 would not violate the spacing requirement of a double-wide trace if it were routed on gridpoint 14₄, assuming the required double-wide spacing is 100 nm. However, in this example, it will induce some noise impact if this exemplar trace is a high power trace and switching along trace 16 propagates disturbances some distance from trace 16.

The depicted method may be used to indicate and store in router data storage, data about a variety of different trace types and other shapes that may be placed on a grid 12 and their impact on proposed routes, paths or segments. The data is then used by search algorithms when finding routes for other traces. Those of skill will recognize that routers implement methods and algorithms with software that induces instructions for implementation of the desired method or algorithm. Those of skill will also recognize that the trace size and spacing used in this example are merely exemplary and it is expected that systems will use a variety of trace sizes and other shapes.

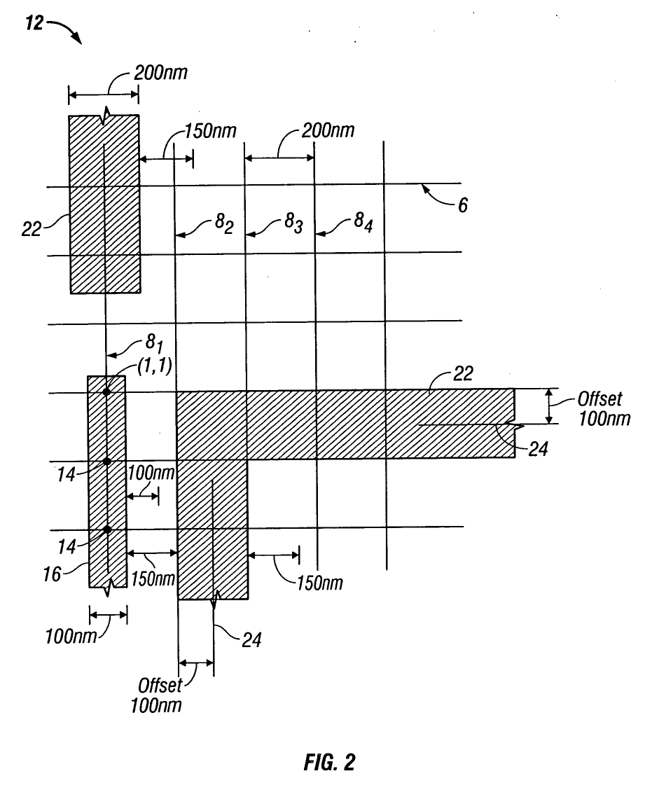

FIG. 2 depicts a method of enhancing grid precision and usability by offsetting traces from gridpoints. The depicted portion of grid 12 has example single wide trace 16 and example double-wide traces 22. Gridlines. 6 and 8 form a standard routing grid having, in this example, a 200 nm spacing. The left-hand exemplar traces 16 and 22 are routed along gridline 8₁. Trace 16 is a single-wide trace with a 100 nm width and a 100 nm spacing requirement. Traces 22 are double wide traces with a 200 nm width and a 150 nm spacing requirement.

The upper depicted double-wide trace 22₁, is centered on vertical gridline 8₁ and therefore blocks gridline 8₁ and gridline 8₂ because gridline 8₂ is within the required 150 nm spacing for the trace 22₁. The first gridline 8 available for routing a single-wide or double-wide trace beside the upper depicted trace 22₁, is gridline 8₃. Because the upper depicted trace 22₁, is centered on gridline 8₁, it blocks not only gridline 8₁, but also the neighboring gridline 8₂ to its right and the corresponding neighboring gridline to its left (not shown). Thus three gridlines 8 are blocked by upper depicted trace 22₁.

In such a scheme, area may be wasted. The example grid size does not allow optimal spacing. To reduce the pitch of the gridlines, however, to achieve more optimal spacing may greatly slow down the routing program by significantly increasing the number of gridpoints searched.

The lower depicted double-wide trace 22₂ is placed according to a preferred method of the invention to help optimize space efficiency, or packing, without decreasing the pitch of the gridlines employed. The lower trace 22₂ is centered on an offset line 24. Line 24 is offset from gridline 8₂ by 100 nm. With such an offset location, the vertical portion of offset placed lower trace 22₂ blocks only two gridlines, 8₂ and 8₃, rather than blocking three gridlines. In this example, gridpoints 14 on gridline 8₁ beside offset lower trace 22₂ may be employed for routing a single-wide trace which is spaced at the correct 150 nm spacing from offset lower trace 22₂. Thus, the depicted method provides more efficiently spaced traces.

A proper offset distance may be determined for a: particular shape such as, for example, a double wide trace, an analog trace, or other special trace, by shifting an outline of the shape with its associated spacing over a desired grid and determining which offset position blocks the smallest number of gridlines. Preferably, the offset position is determined in advance of the routing step. The offset position is preferably associated with a particular type of trace or shape being placed on a particular size grid. Some combinations of a grid and a shape will not have any offset distances that would unblock gridlines.

Offset lower double-wide trace 22₂ may be stored as a data structure having data fields for the type of trace, the route of the trace, and for the offset distance. In another embodiment, an offset distance may be predetermined for a particular shape on a particular sized grid. In such a case, the offset characteristic may be stored as a tag such as a one-bit tag indicating that the shape is offset, with no indication of the offset distance in the trace data structure.

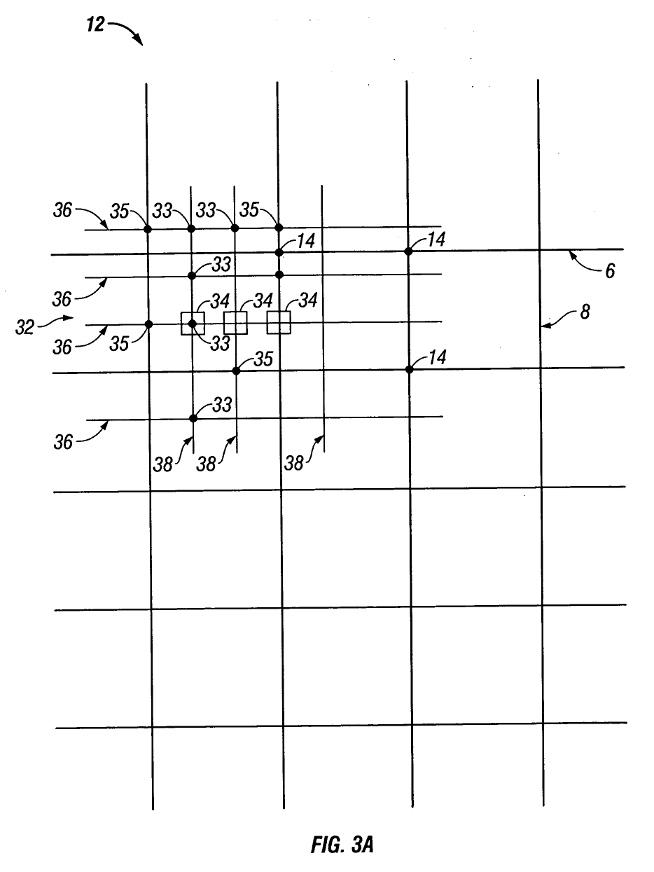

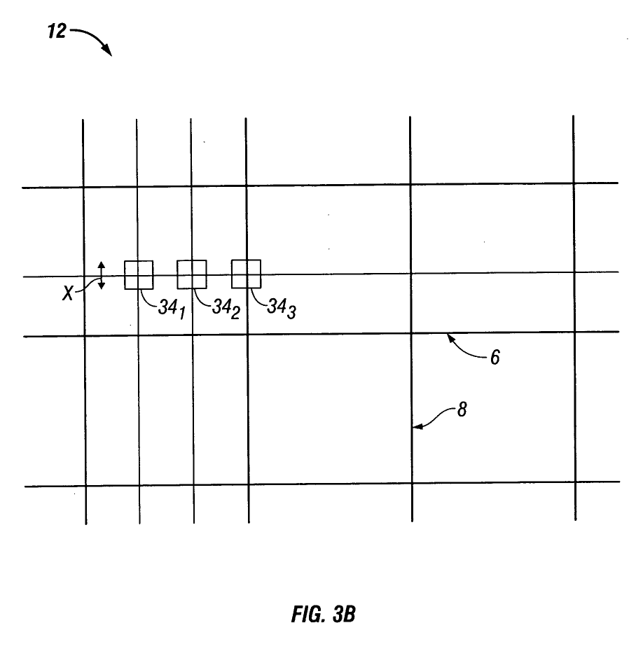

FIG. 3A depicts a routing grid enhancement scheme using a subgrid. Depicted is a portion of a routing grid 12 formed by gridlines 6 and 8. A typical trace is routed by designating a route of successive gridpoints 14. In the depicted example, pins 34 are to be connected to some other point elsewhere in the area covered by the routing grid. Depicted pins 34₁ and 34₂ are, however, found to not be on a gridpoint 14. Such offset pins 34 may present a problem for a typical grid-based routing engine because they may not be reached by a trace on routing grid 12.

In an embodiment of a preferred routing system embodiment of the invention, a trace to an offset pin 34 will be routed using a subgrid 32. In a preferred embodiment, a subgrid is generated and data of the subgrid that is unnecessary for a routing step is suppressed or deleted to increase router search efficiency.

The depicted routing grid 12 may have, for example, a 100 nm pitch. While the right-hand depicted pin 34₃ is on gridline 8 of routing grid 12, the two other depicted pins 34₁ and 34₂ are found to be off grid 12. Such a situation may arise when the position of a semiconductor device within an integrated circuit has constraints that do not allow optimal placement. The device having terminals at pins 34 may be, for example, a transistor disposed at a semiconductor layer beneath the metal trace layer for which routing is performed on the depicted routing grids 12 and 32. In this example, subgrid 32 is generated based on the inter-pin distance of pins 34 or it may be generated based upon the size “X” of a pin 34 as shown in FIG. 3B or the subgrid may be spawned from a pin 34 known to be offset from the main grid 12. The pitch of depicted subgrid 32 is 40 nm, but this is only exemplary and, as with other Figs. of this disclosure, features should not be considered drawn to scale.

FIG. 3A illustrates the generated subgrid 32. The generated subgrid 32 has gridlines 36 and 38 which intersect to form gridpoints 33. Gridlines 36 and 38 also intersect with at least one gridline 6 or 8 to form common gridpoints 35.

After generation of the subgrid, a shrink or poll is done to determine the data associated with subgrid 32 that is not needed by a particular connection to be routed. The unneeded data is suppressed or deleted. This increases the search speed in the subgrid area. Thus, only required data for a proposed connection is searched. This is done iteratively and data not necessary for routing the next connection is suppressed or deleted. FIG. 3A illustrates a spawned subgrid 32 before deletion of unneeded data and FIG. 3B illustrates the subgrid area after deletion of unnecessary data. Those of skill will recognize the increased efficiency of searching in subgrid areas where unneeded data has been removed from the search and the concomitant advantage of reduced fracturing of the routing plane.

In use, a typical computer driven router employs a search algorithm that searches for routes on grids such as, for example, subgrid 32 and routing grid 12. A search typically proceeds outward from an origin point in wave fronts or “waves” evidenced by gridpoints labeled commonly from the origin. For example, those gridpoints equidistant from the origin are labeled with the same value to allow searching on the cost criteria of distance from the origin. For example, a wave propagated outward from origin point “S” will result in labeling gridpoints that reside 1 grid unit from S with a value label of “1”. When the wave 1 points have been labeled, the search algorithm starts at each labeled wave 1 point and searches for unlabelled, and open, neighboring points which are then labeled wave 2. Many search algorithms consider a gridpoint adjacent only if it is along the “edge” of a grid square, between two gridpoints on the same gridline. Others may allow diagonal movement. The search typically proceeds until the destination point is labeled. This is known as a “maze search”.

Referring to FIG. 3A, in a searching method for off-grid pins, such as exemplar off-grid pins 34₁, and 34₂, the typical wave number search, scheme may be modified. For example, it may be seen from the depiction that the gridpoints 33 of subgrid 32 are closer together than gridpoints 14 of routing grid 12. A search algorithm would not, therefore, be optimal if it designated a “step” along an edge from subgrid 32 having the same wave numbers as “step” along an edge of routing grid 12.

One technique, therefore, is to label gridpoints in a search with a “cost” that relates to distance. For example, subgrid 32 in FIG. 3A has edges of grid square that are ⅓ the length of routing grid 12's grid square edges. A search algorithm search for a route on through both subgrid 32 and routing grid 12 may label each step on subgird 12 with a wave number that has a “cost” element. For the depicted scheme, such a cost element includes distance. For example, a search may label the subgrid point 33 one edge away from the origin point 33 with a “cost” of “1”. The search would proceed in such increments until a gridpoint 14 is labeled, meaning that the search has found a route off of subgrid 32 and onto the main routing grid 12. Then, each successive wave adds cost increments of “3” instead of one to the wave number, reflecting a cost element in the wave number that is proportional to the distance between adjacent gridpoints on grid 12.

In some embodiments of the present invention, higher informational cost data may be incorporated into a wave or wave count evaluation to assess the impact one choice of route may have over another possible route for the same connection. As earlier alluded to, vertices on the grid (or subgrid) may be labeled with cost information implicit in which is an indication of adverse impact upon an attribute of interest (e.g., reduced delay, noise tolerance, manufacturability) for connections that employ that particular vertex.

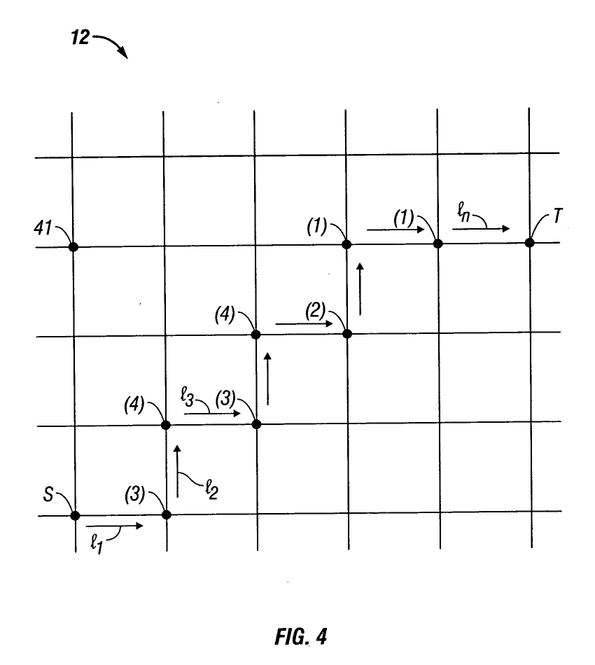

For example, with reference to FIG. 4, a possible path between a source “S” and a target “T” will typically have a plurality of steps or segments l₁, l₂, l₃, * * * lₙ. Considering each vertex as a point 41, each point 41 (or segment bounded by that point —i.e., associated segment) in any potential path from S to T has been evaluated by an optimization tool based upon the cost that will impinge upon an attribute of interest (e.g., reduced delay, noise tolerance, manufacturability) from use of that point 41 or associated segment in the possible path. In FIG. 4, a proposed connection path from S to T has eight segments l₁, l₂, l₃ * * * l₈, each of which has been evaluated by an optimization tool to have a particular impact or cost upon one or more attributes of interest. In this case, a “terrain cost” is determined by summing the length of each segment (lᵢ) factored by a cost weighting (wᵢ) or:
Σlᵢwᵢ=terrain cost. (1)

The summation of equation 1 is taken from S to T. Equation 1 does not, however, include another cost of interest, namely, the shape cost which is an expression of the intrinsic impact on the attribute of interest by the shape selected for the connection or segment (e.g., single wide, double wide, triple wide trace). Thus, a preferred embodiment incorporates terrain cost, shape cost and segment length to develop a wave that allows more accurate assessment of the impact a particular route will have upon an attribute of interest. Thus, equation 2 expresses an incorporation of terrain costs, shape costs and segment lengths to render a more accurate cost assessment:
Σlᵢ(wᵢ+sᵢ). (2)
Where the sum wᵢ+sᵢ is the minimum sum of terrain and shape cost for allowed shapes for the segment 1ᵢ.

In some embodiments of the invention that employ equation 2, waves are spawned that express a more effective cost assessment. This method, although providing more information, can burden the computational engine of the routing system to result in slow routing.

Now, in the just described method, if lᵢ=1 for all l, then from S to T:
Σlᵢwᵢ=Σwᵢ. (3)

An alternate preferred method employs, however, a less computationally demanding approach. It has been determined by the assignee that a router using an algorithm according to equation 4 below will typically select a route that would have been selected using equation 1 (i.e., the sum of the multiplications of length and weight).
Σwᵢ+Σl_{i.} (4)

Where each of the summations is taken from S to T.

Although the literal cost for a route from S to T will differ between equations 1 and 4, cost figures are, as those of skill will recognize, arbitrary and only have meaning relative to another cost figure computed under the same scheme. Therefore, although the absolute magnitudes may differ between routing methods according to preferred embodiments that compute in accordance with either equations 1 or 4, lower cost routes can be identified by each while the preferred method of equation 4 will typically be faster.

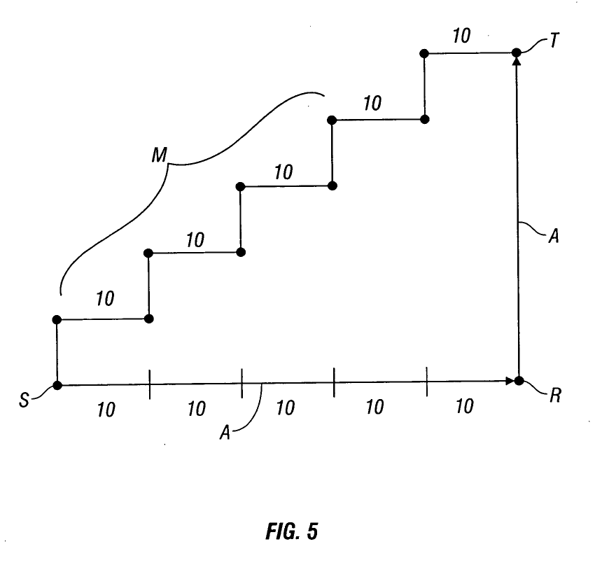

A preferred method of the invention is exemplified with reference to FIG. 5. In depicted FIG. 5, a first search wave is projected from S as far as possible until inhibited which, in this disclosure, shall mean it is either blocked by an obstacle or the wave has gone beyond the target T. Then, a second search wave is spawned from what will be called diversion point R (which is the terminus of the first wave) until T is reached. This creates path A indicated on FIG. 5. To reach T may require subsequent waves (e.g., third or fourth waves or more) but there will be fewer bends than in typical more incremental path M.

Thus, in the example of FIG. 5, additive equation 4 is employed to determine the relative cost of path A. In some preferred modes, where more than one shape must be used in a connection, another component of shape cost may be added to the evaluation. Thus, the following equation illustrates another more efficient method to incorporate terrain costs, shape costs, and segment lengths in a cost assessment:
Σ(wᵢ+sᵢ)+Σl (5)
where as before, the sum wᵢ+sᵢ is the minimum sum of terrain and shape cost of any shape that is allowed for segment lᵢ. Even with the more informational equation 5, search time is reduced from the more computationally demanding equation 2. As those of skill will recognize, there may be rare instances where use of the above described methodology with an equation 4 based router system will exhibit slightly longer or costlier paths but such methods have subsidiary benefits such as reduced bend count that likely compensate for such shortcomings.

Thus, a preferred embodiment of systems and methods in accordance with the present invention allows for the optimization of routes based on a plurality of attributes or criteria (e.g., reduced delay, noise, or manufacturing) that are expressed as costs for the shapes that may be used for routing a connection (through shape cost), as well as interaction of a selected shape with shapes of other connections (through terrain cost). These costs are additive and may be changed to emphasize one criterion or attribute over another. In some of the preferred systems and methods that employ these advantages, the cost function is modified to minimize the impact on run-time of a maze search without adversely impacting the optimality of the solution.

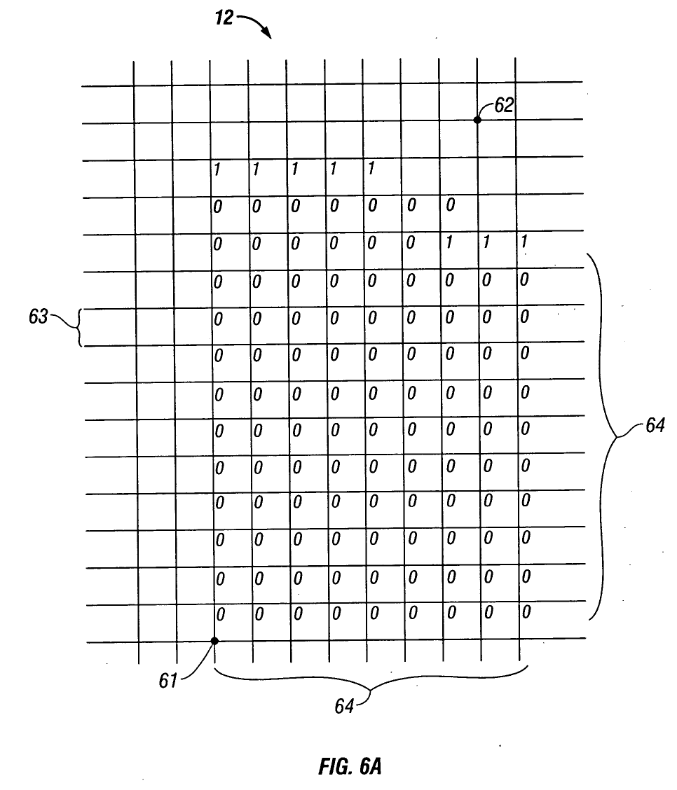

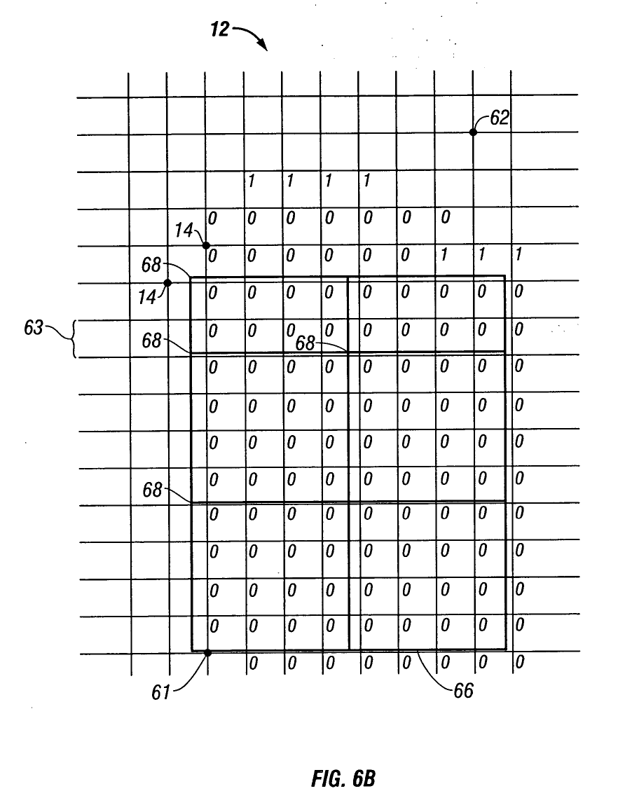

FIG. 6A and FIG. 6B illustrate a sparse grid flyover technique according to one embodiment of the present invention. In the depicted example in FIG. 6A, a routing algorithm is employed to route a trace on routing grid 12 from source gridpoint 61 to destination gridpoint 62. In the depicted status of grid 12, a large field 64 of gridpoints is unblocked. The unblocked field is indicated by the large brackets 64. Small bracket 63 indicates a break, which may be very large. The depicted example shows a field of less than 200 gridpoints, but this is exemplary only and typical routing situations may have empty fields with dimensions in the thousands of gridpoints.

In the early stages of routing a particular integrated circuit design, for example, many large areas may be empty of routes or blocked gridpoints. In such a situation, a search algorithm may have to search large fields of unblocked gridpoints. Such a search will typically be much slower than the optimum possible search. To increase the speed of a search across a large field of unblocked gridpoints, a sparse routing grid may be applied over the routing grid 12.

FIG. 6B depicts a sparse routing grid 66 covering unblocked field 64. Sparse touting grid 66 is preferably generated as a temporary data structure and maintained long enough to route one or more desired traces across unblocked field 64. While the depicted sparse routing grid 66 is shown slightly offset from routing grid 12 for enhanced clarity of explication, preferably each horizontal and vertical gridline of sparse routing grid 66 is disposed directly on a routing grid 12 gridline.

Preferably, the sparse routing gridpoints 68 that are on the exterior of sparse routing grid 66 are considered, for searching purposes, to be adjacent to their neighboring gridpoints 14 that are outside of the area covered by sparse routing grid 66. For example, the depicted left-upper gridpoint 68. is adjacent to the two adjacent referenced gridpoints 14. Such a scheme allows a routing algorithm to search for a route on gridpoints 68, and continue searching on finer gridpoints 14 when the search reaches the exterior of sparse routing grid 68.

In this example, each step along sparse routing grid 66 may have a cost of 4. In such case, a step from the upper-left depicted gridpoint 68 to one of its adjacent points 14 has a cost of 1. The sparse routing grid 66 may, of course, have a different pitch, such as, for example, 2 times, 6 times, 8 times, or more of the pitch of routing grid 12. For very large unblocked field 64, a larger pitch is preferred. The advantage in search speed may be readily understood from the depicted sparse routing grid, where four gridpoints 68 are searched to cover an area having 25 gridpoints 12.

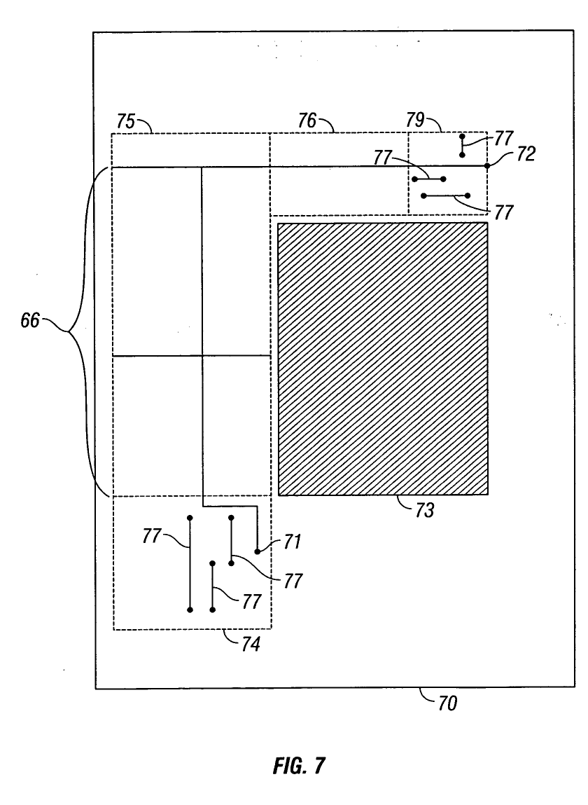

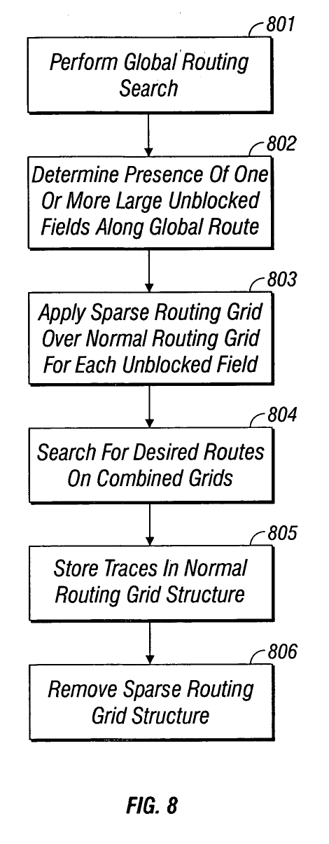

FIG. 7 depicts a global routing scheme using sparse routing grids 66 according to one embodiment of the present invention. Depicted is a portion of one metalized layer 70 on which traces are routed. To simplify the depiction, gridlines are not shown. FIG. 8 depicts a flow chart for a routing scheme using sparse routing grids. The sparse routing employed in a preferred embodiment of the present invention is done by regenerating an appropriate grid dynamically.

With reference to FIGS. 7 and 8, a netlist requires a trace to be routed from point 71 to point 72. Although only a simple routing between two points is used an example, a search typically performs global routing for many traces at once. For example, a data bus may be routed from one area to another having several data traces.

In one preferred embodiment of the present invention, a route search performs a global search for general areas through which the desired trace should be routed (Step 801). In this example, area 73 is blocked. The global routing step 801 chooses a global route having regions 74, 75, 76, and 79. Regions 74 and 79 are congested and therefore, tighter searching will be required in those regions.

In step 802 of the embodiment referred to by FIG. 8, the presence of large unblocked areas. Such searches may consist of series flyover methods, row and column summation methods, wave search methods, or other methods suitable for determining that a large area is unblocked.

In this example, regions 74 and 79 have multiple pins and several traces 77 already shown as having been routed therein. Regions 75 and 76, however, are determined to be sparse. Step 802 may search for unblocked regions that are subregions of a larger global routing region produced by step 801. The search of step 802 has, in preferred modes, a required size for each unblocked region that is selected to reduce the computational load for the search. For example, if a certain regions with 200 gridpoints edges would require more computations to create and employ a sparse routing grid than would a search of a normal routing grid, the normal routing grid would be employed. Another region may have edges larger than several thousand gridpoints. In such a case, step 802 may implement a sparse routing grid 66 to improve search efficiency because such a grid would be faster than the normal routing grid. Such size determinations may be pre-computed or selected for various trace types and grid size combinations.

In step 803, after spare areas or regions are identified, sparse routing grids 66 are applied over the identified unblocked regions 75 and 76. Note that spare regions may overlap denser regions in a lower layer. Preferably, data structures for the sparse routing grids 66 exist simultaneously to allow search algorithms to complete entire traces in step 804. The search step 804 employs sparse routing grids 66 and normal routing grids 12 in combination as described with reference to FIGS. 6A-B. While, in this example, two global routing regions 75 and 76 have sparse routing grids 66 applied, grids of more or less density may be used and one particular region may have more than one sparse routing grid applied within it. Further, sparse routing grids may share edges or be a “combined” grid that is not necessarily rectangular in shape. For example, a data structure may contain a single shaped grid to cover global routing regions 75 and 76, or two data structures may be used. If two are used, adjacent sparse routing grids may have gridpoints that are considered adjacent for search purposes. For example, a request for adjacent gridpoints to a sparse routing gridpoint at the right-hand edge of depicted region 75 may return a sparse routing gridpoint on a sparse routing grid covering area 76.

While routing on one layer is shown, those of skill in the art will understand, after appreciating this specification, that the techniques described herein are often applied across designs having more than one routing layer. For example, many integrated circuits have one or more metalized layers with a preferred horizontal trace direction, and one or more metalized layers with a preferred vertical trace direction. Routing algorithms frequently search for routes that span the various layers and are connected by vertical connection vias. Regions 75 and 76 may, for example, be on different layers.

In step 805, the routed traces resulting from search step 804 are stored in a database or data structure compatible with a normal routing grid 12. Such storage is preferably accomplished after each individual trace search is complete. In step 806, after routing the considered trace from 71 to 72, data structures for sparse routing grids 66 are preferably removed from the database or data structures store associated with routing grid 12.

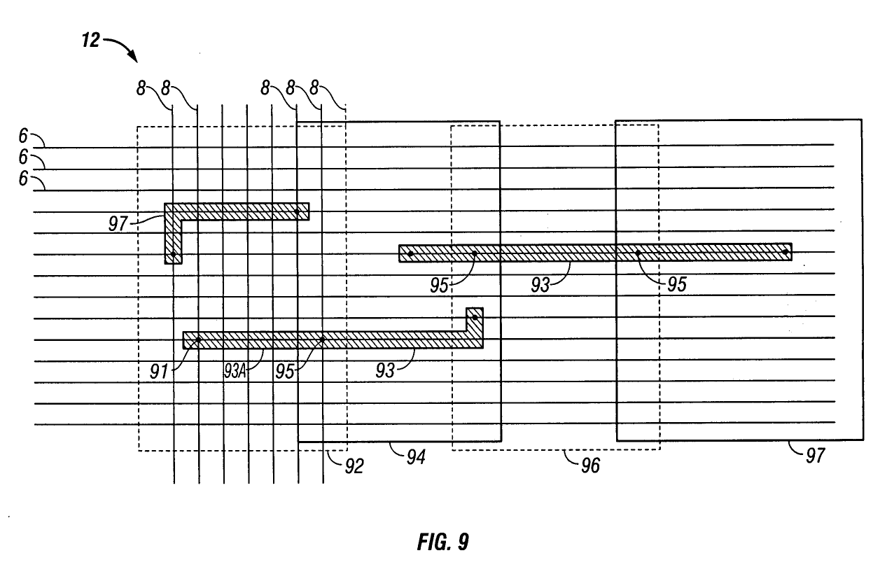

FIG. 9 illustrates a parallel processing routing scheme according to one embodiment of the present invention.

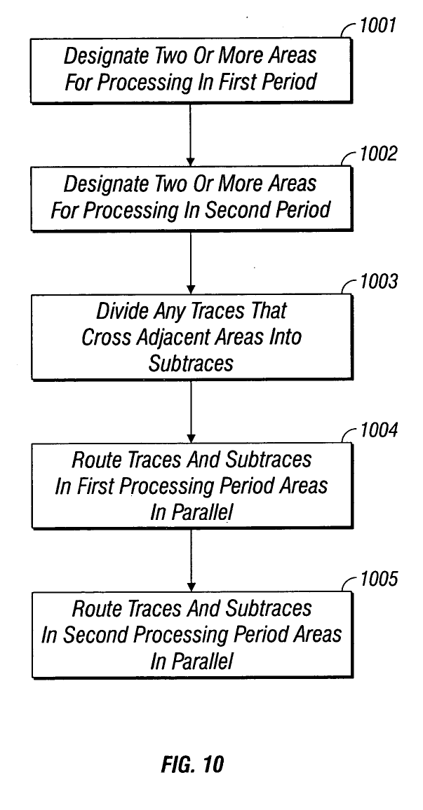

FIG. 10 depicts a flow chart of a parallel processing routing scheme according to one embodiment of the present invention.

Referring to FIG. 9 and FIG. 10, sometimes millions of traces need routing on grids with immense numbers of gridpoints. Often, a routing system slows the design process for a particular integrated circuit because of the extreme numbers of traces that require routing in a densely populated design. A scheme for processing in parallel greatly improves the speed at which such routing may take place. Parallel processing typically involves the simultaneous use of more than on microprocessor, computer, processor core, or other structure for processing algorithms.

Several complexities place constraints on systems for implementing such a parallel processing scheme. For example, a routing search algorithm preferably should not use resources that may be used by another search algorithm operating in parallel. One such resource is the datastructure holding “blocked/unblocked” information for a particular gridpoint. If one routing algorithm uses or blocks a gridpoint that is also used by a simultaneously-running routing algorithm, a flawed design may result. That is, the two traces produced by such a situation may violate an electrical rule or other design rule. Preferably, a parallel processing scheme does not require communication between processors as they work on their assigned parallel tasks.

The scheme depicted in FIG. 9, all or a portion of routing grid 12 is divided into areas or zones. Vertical gridlines 8 are not shown over the entire view to simplify the drawing. Nevertheless, in this example, the entire area discussed is covered with a routing grid 12. The depicted example has areas 92, 94, 96 and 98. Step 1001 in FIG. 10 designates areas 92 and 96 to be processed during a first parallel processing period. As can be seen, areas 92 and 96 are not overlapping and are not adjacent- they are separated by a separation distance. This distance is preferably greater than any distance over which a relevant electrical or other design rule may have any effect. Such a scheme helps avoid any need to communicate between processors. For example, if a certain analog or high voltage trace requires a large keepout area, then the separation distance between areas 92 and 96 should be at least as large as such keepout area. Different layers or different regions of a layer may have different trace types with different rules. If no rule exists that specifies any trace routed on a gridpoint will affect a neighboring gridpoint, then, as those of skill will appreciate, areas 92 and 96 may be adjacent. Such case is not typical.

Step 1002 designates areas 94 and 98 to be processed during a second parallel processing period. The second period is preferably subsequent to the first period. As can be seen, areas 94 and 98 are non-overlapping and non-adjacent. Area 94 overlaps area 92. Such overlap is preferable so that any traces which require routing in both area 92 and 94 can be divided into subtraces that meet at a common point inside the overlap area.

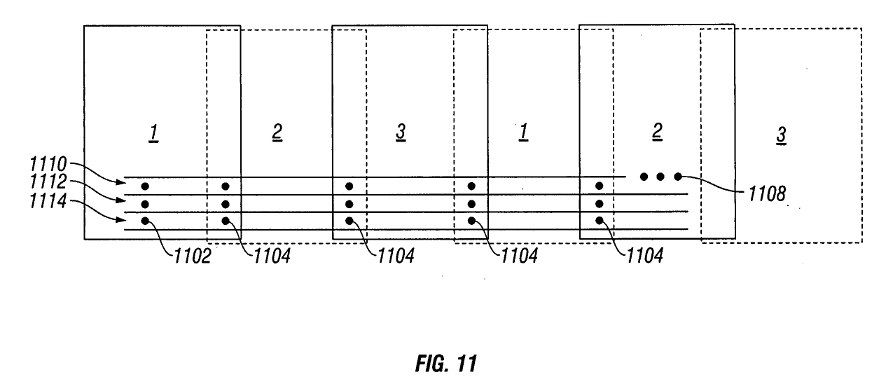

While areas are shown for processing in two processing periods, the concept may of course be extended to more than two processing periods. For example, one or more areas for processing in one or more additional processing periods could be placed in the scheme between area 94 and 96, with further areas placed to the right of area 98. Another examples of such a scheme is depicted in FIG. 11. In addition, any number of areas may be routed in parallel in a given processing period.

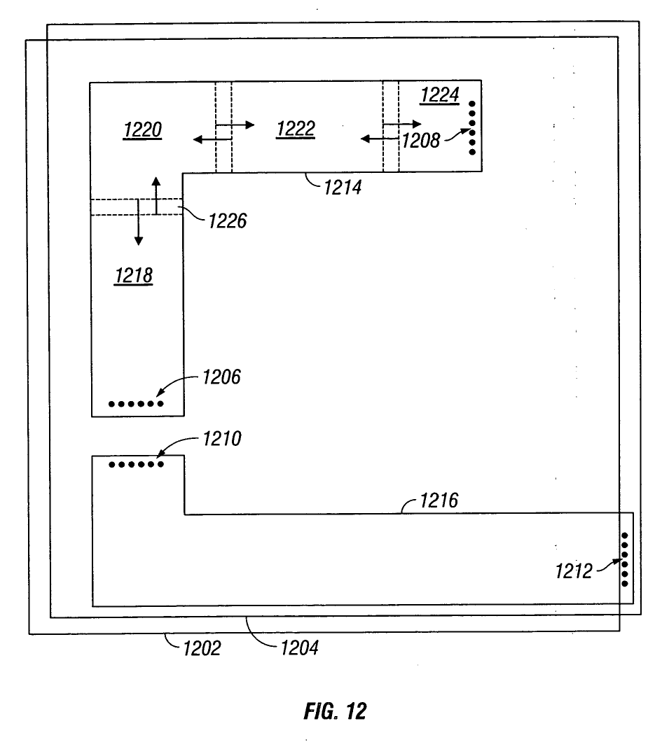

Step 1003 determines the presence of multi-area traces and divides them into subtraces 93. Example multi-area traces 93 are shown, having endpoints at virtual pins 95 in the overlap area. Step 1003 determines the location of virtual pins 95, typically before the search for a route in any particular area. Step 1003 may, in some embodiments, be integrated with a global routing search phase. One such embodiment is described in more detail below with reference to FIG. 12.

Step 1004 performs route searches for traces in areas 92 and 96 simultaneously. For example, subtrace 93A is routed in step 1004. Subtrace 93A is the portion of the lower depicted trace 93 between its origin point 91 and virtual pin 95. Also routed in step 1004 are traces 97 that are entirely within area 92 or area 96. There is no trace 97 in area 96 in FIG. 9.

In a preferred embodiment, a separate processor searches for routes for each of areas 92 and 96. The processors run in parallel. Such processors are preferably coupled to a common memory which contains database structures for storing completed traces. Such storage is sometimes referred to as “trace storage” or “wire storage”. The parallel-running processors may be part of multiprocessor computer systems, may be in separate computer systems, or may, for example, be processor cores arranged on a common integrated circuit. Other structures for processing algorithms in parallel and combinations of any suitable parallel processing structures may be used.

Step 1005 performs route searches for traces and subtraces in areas 94 and 98 simultaneously. The depicted traces in FIG. 9 are fixed in their location after searches are performed in the various areas. Areas 94 and 98 may be processed in parallel because they, too, do not employ shared resources.

FIG. 11 illustrates a parallel processing routine scheme according to another embodiment of the present invention. The depicted dotted and solid lines define zones or areas of a larger region for which routing of traces is required. The zones or areas are labeled 1, 2, and 3 to indicate the parallel processing period in which they will be processed. Both of the depicted areas 1 will be processed simultaneously by separate processors. Subsequently, after routes have been recorded for processing period 1, routes in the areas marked 2 will be processed. Next, routes in the areas marked 3 will be processed.

The depicted three-period scheme is only exemplary and other embodiments may have two or more than three periods. Further, while routing grids are shown in some examples herein, the described parallel processing scheme may be implemented to advantage on systems that do not employ routing grids.

FIG. 11 also illustrates a track assignment scheme according to one embodiment of the present invention. The embodiment of a routing system has a track assignment step before performing parallel processing searches for routes. The pin designated 1102 requires connection to three pins at 1108. The track assignment step assigns a track along the overlap areas for each of the depicted pins. The track designates where the virtual pin should be placed. For example, the depicted lower pin 1102 is assigned a track 1114 designated by dotted lines. The virtual pins, which form endpoints for parallel processing subtraces, are placed in the track. The other depicted pins above pin 1102 are assigned tracks 1110 and 1112. Such a track assignment step is preferably performed after any global routing and before parallel processing begins.

FIG. 12 illustrates a global routing function employed in combination with a parallel processing function in a scheme according to one embodiment of the present invention. A sparse routing grid and detailed subgrid scheme may also be employed with the illustrated scheme.

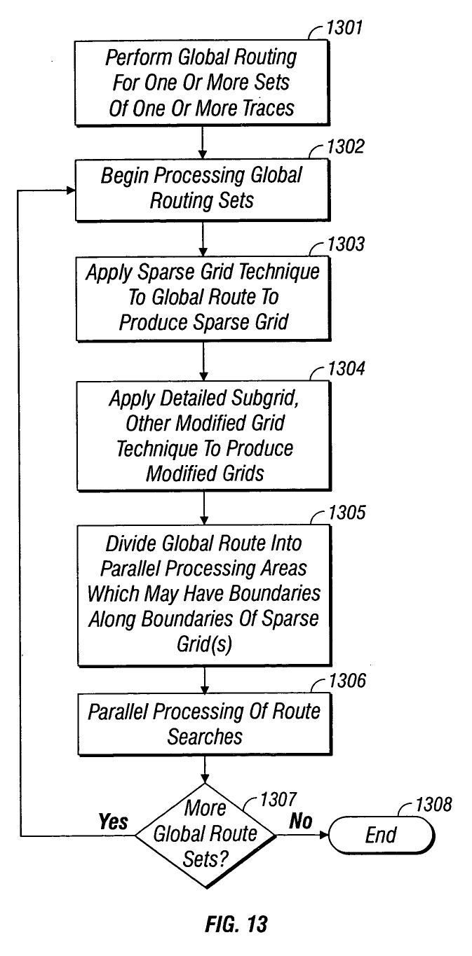

FIG. 13 depicts a flow chart of a global routing function employed in combination with a parallel processing finction according to one embodiment of the present invention.

Referring to FIG. 12 and FIG. 13, a netlist having a required set of traces or wires to be routed is processed to find routes. In this example, the routing system searches for routes on two metallized layers, 1202 and 1204. This number of layers is merely exemplary. Some complicated integrated circuits have many layers and some circuits have few or one layer. The concepts described herein may be employed on many of such circuits. This example shows only a few groups of pins requiring interconnection. In a typical situation that may employ to advantage the techniques described herein, many more pins require interconnection across much larger relative spaces than is depicted in the simplified examples herein. In FIG. 12, a first set of traces requires routing from pins 1206 to pins 1208. A second set of traces requires routing from pins 1210 to pins 1212.

In this embodiment, a global routing system begins the process of finding routes for the required traces and performs a global routing search for routes in step 1301 (FIG. 13). Global routing searches are known and used in the art to determine general areas through which a set of routes will pass. Step 1301 finds global routing area 1214 through which the set of traces from pins or terminals 1206 will pass to pins 1208. Step 1301 also finds global routing area 1216 through which routes for traces from pins 1210 to pins 1212 will pass. Global routing may also determine which layer a certain trace may occupy. Alternatively, the detailed routing search algorithm may determine a layer change. Often, one layer is preferred for x-direction traces and another for y-direction.

Step 1302 begins detailed searching for a particular global routing area having a set of traces for which routes must be found. Step 1303 applies sparse grid techniques such as those described with reference to FIG. 6 through FIG. 8. In this example, step 1303 finds unblocked area 1218 in which a sparse routing grid may be applied. Area 1218 has an edge at the dotted line with the arrow pointing to reference 1218. That is, area 1218 and its adjacent area 1220 overlap. In this example, suppose much of area 1220 has blocked portions that preclude employing a sparse grid. Area 1222, however, is unblocked. A sparse grid may, consequently, be applied over area 1222. Step 1305 produces the data structure for such sparse grids and interconnects it, preferably temporarily, to a background normal routing grid 12 data structure such that search algorithms; may employ both sparse and normal routing grids.

Step 1304 applies other grid modification techniques such as, for example, a detailed subgrid which may be employed in area 1224 to route connections to pins that may be offset from the routing grid 12. Step 1304 similarly may produce temporary modified grid structures on which a search algorithm may search for a route portion as it finds the original route for a particular trace or subtrace. Subtraces are, in many embodiments, treated exactly as traces are treated by search algorithms.

Step 1305 divides the global route being processed into parallel processing areas. For example, areas 1218 and 122 may be designated as first parallel processing period areas, and areas 1220 and 1224 may be designated as second parallel processing period areas. Step 1305 preferably makes minor adjustments in the boundaries of the areas to obtain proper overlap so that virtual pins may be placed in an overlap area accessible during processing of each adjacent area. Preferably, the overlap area is at least two gridsquares wide to allow for placement of virtual pins in the middle of the area. For example, in the overlap area 1226 of areas 1218 and 1220, the top row of sparse routing grid squares is present with the bottom row of normal routing grid squares from the routing grid in area 1220.

Step 1305 further assigns locations for virtual pins at which subtraces are terminated. Such assignment may be accomplished by a track assignment scheme such as that described with reference to FIG. 11.

Step 1306 performs parallel processing for the various areas according to techniques such as those described with reference to FIG. 9-FIG. 11.

Step 1307 checks for global route sets which may need routing. In this example, the set traces in global routing area 1216 also require routing, so the process returns to step 1302 to route the connections in global routing area. 1216.

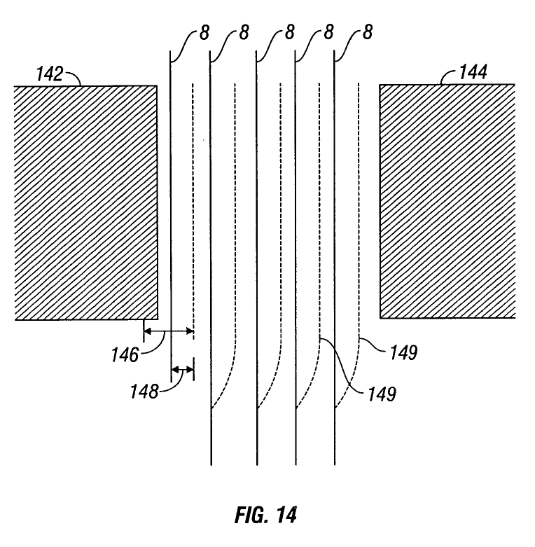

FIG. 14 illustrates a grid adjustment scheme according to one embodiment of the present invention. In this example, a routing grid is used to route traces for one or more metal layers. Only vertical gridlines 8 are shown to simplify the drawing. The depicted vertical gridlines 8 are arranged between two routing blockages 142 and 144. A routing blockage can be a power bus, electrically isolated circuitry, or a physical edge or other keepout area. In the depicted example, the left-hand gridline 8 is disposed so near to routing blockage 142 that part of blockage 142 is in keepout area 146 of gridline 8. Such a situation allows use of only four of the five gridlines passing through the routing area. It is possible, however, that all five gridlines may be employed.

In a preferred method of this embodiment, a routing system detects such a situation and applies a shift to the gridlines. The shift is depicted as a shifted distance 148, which movies gridlines 8 to new gridline locations 149. The shift is preferably applied only locally, but may be applied to the entire gridline. Various methods may be used to implement the shift, such as, for example, adding offsets to all traces in the area, or changing recorded coordinates of the affected gridlines.

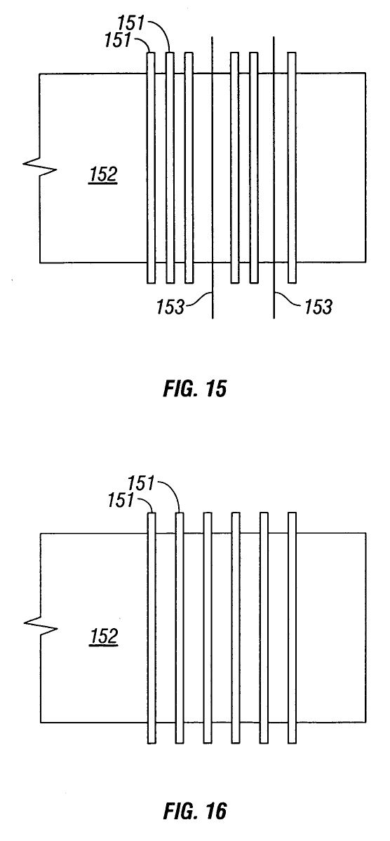

FIG. 15 and FIG. 16 illustrate a trace adjustment scheme according to one embodiment of the present invention. In this example, the depicted six traces 151 cross an portion of a grid area 152. The depicted portion is selected only because it has a fixed number of traces routed across it, the traces having blank gridlines 153 between some of them. The exemplar arrangement could hold two more traces arranged along the gridlines 153, but there are no more required traces to be routed.

In such a situation, it is beneficial for electrical noise performance to increase the spacing between each trace. This can be accomplished by spreading the extra space taken by the two empty gridlines among the remaining traces. If the six traces are all of the same size and type, the space is preferably divided equally. If any traces have more stringent requirements for electrical noise, those may, in some embodiments, be given a larger allotment of space.

The resulting arrangement is shown in FIG. 16 with the six traces 151 spaced evenly along portion 152. Such an adjustment is preferably done after routing by adjusting coordinate data associated with the traces. An adjusted routing grid may also be used similar to FIG. 14.

Although the present invention has been described in detail, it will be apparent to those skilled in the art that many embodiments taking a variety of specific forms and reflecting changes, substitutions and alterations can be made without departing from the spirit and scope of the invention. The described embodiments illustrate the scope of the claims but do not restrict the scope of the claims.

1. A method for evaluating a selected path segment for potential use in a possible path for a connection in an integrated circuit, the method comprising the steps of:
associating a cost matrix with a selected path segment from a first gird vertex to a second grid vertex, the cost matrix expressing an first matrix value related to an impact upon an attribute of interest that incorporation of the selected path segment into the possible path would have if articulated with a first shape, the first matrix value taking on one of three or more available first matrix value range values.

2. A computer program for a routing system, the computer program comprising one or more computer readable medium having computer executable instructions which, when executed by one or more processors, implement the method of claim 1.

3. The method of claim 1 in which the cost matrix expresses a second matrix value related to the impact upon the attribute of interest that incorporation of the selected path segment into the possible path would have if articulated with a second shape, the second matrix value taking on one of three or more available second matrix value range values.

4. The method of claim 1 in which one of the three or more available first matrix value range values represents prohibition of use of the selected path segment in the possible path if articulated with the first shape.

5. The method of claim 3 in which one of the three or more available second matrix value range values represents prohibition of use of the selected path segment in the possible path if articulated with the second shape.

6. The method of claim 1 further comprising the step of assigning the one of the three or more available first matrix value range values with an optimization tool.

7. The method of claim 3 further comprising the step of assigning the one of the three or more available second matrix value range values with an optimization tool.

8. A method of routing a net within an integrated circuit layout, the method comprising the steps:
finding a route available for a first single-wide trace;
placing a second trace along the route, the second trace being wider than single-wide;
shifting the second trace by a gridline offset distance, the gridline offset distance devised to reduce a number of gridlines blocked by the second trace.

9. A computer program for a routing system, the computer program comprising one or more computer readable medium having computer executable instructions which, when executed by one or more processors, implement the method of claim 8.

10. The method of claim 8 further including the step of designating a grid pitch equal to a designated width of a single-wide trace plus a designated spacing for a single-wide trace.

11. The method of claim 8 in which the second trace is a double-wide trace.

12. The method of claim 8 further including the step of storing, in a trace storage data structure, a data record for the second trace, the data record containing an indication that the second trace is offset.

13. The method of claim 12 in which the data record contains a trace type designation and a designation that the trace is offset.

14. The method of claim 13 further including the step of predetermining one or more offset distances each corresponding to a selected one of one or more different types of traces.

15. The method of claim 14 in which the step predetermining one or more offset distances includes determining offset distances for more than one grid size.

16. The method of claim 14 in which data record does not contain an indication of the gridline offset distance.

17. A method for routing one or more netlist connections amongst a plurality of pins, the one more netlist connections including at least one path from a first pin to a second pin where at least one of the first and second pins is not located on a main grid, the method comprising the steps of:
generating a first subgrid that results in an intersection of a gridline or vertex of the first subgrid with the at least one of the first and second pins that is not located on the main grid;
determining data associated with the first subgrid that is not needed for the at least one path from the first pin to the second pin;
suppressing the data determined to be not needed for the at least one path from the first pin to the second pin.

18. A computer program for a routing system, the computer program comprising one or more computer readable medium having computer executable instructions which, when executed by one or more processors, implement the method of claim 17.

19. The method of claim 17 further comprising the step of routing the at least one path from the first pin to the second pin.

20. The method of claim 19 wherein the one or more netlist connections amongst a plurality of pins includes at least one path from a third pin to a fourth pin where at least one of the third and fourth pins is not located on the main grid and further comprising the steps of generating a second subgrid that results in an intersection of a gridline or vertex of the second subgrid with the at least one of the third and fourth pins that is not located on the main grid;
determining data associated with the second subgrid that is not needed for the at least one path from the third pin to the fourth pin;
suppressing the data determined to be not needed for the at least one path from the third pin to the fourth pin.

21. A computer program for a routing system, the computer program comprising one or more computer readable medium having computer executable instructions which, when executed by one or more processors, implement the method of claim 20.

22. The method of claim 20 comprising the further step of routing the at least one path from the third pin to the fourth pin.

23. The method of claim 20 in which the first subgrid and the second subgrid include the same data.

24. A method of routing a net within an integrated circuit layout using a routing grid, the net comprising one or more unaligned pins that are not on a gridpoint of the routing grid, the method comprising the steps:
creating a subgrid overlaying the routing grid having a gridpoint on which at least one of the one or more unaligned pins is situated;
finding a route for the net on the subgrid and the routing grid;
storing the route;
determining a first path in the route for the net that connects a first one of the one or more unaligned pins;
determining first data associated with the subgrid that is not needed to route the first path in the route for the net that connects the first one of the one or more unaligned pins;
deleting the determined first data;
routing the first path in the route for the net that connects the first one of the one or more unaligned pins.

25. A computer program for a routing system, the computer program comprising one or more computer readable medium having computer executable instructions which, when executed by one or more processors, implement the method of claim 24.

26. The method of claim 24, further comprising the step of:
recreating the subgrid;
determining a second path in the route for the net that connects a second one of the one or more unaligned pins;
determining second data associated with the subgrid that is not needed to route the second path in the route for the net that connects a second one of the one or more unaligned pins;
deleting the determined second data;
routing the second path in the route for the net that connects the second one of the one or more unaligned pins.

27. The method of claim 24 in which the subgrid covers an area having edges on the order of three times the size of a gridpoint spacing of the routing grid.

28. The method of claim 24 in which the subgrid covers an area having edges on the order of ten times the size of an inter-pin spacing.

29. The method of claim 24 in which the step of creating a subgrid is done dynamically in response to a selection of the net for routing.

30. A method for evaluating a possible path in routing a connection in an integrated circuit, the possible path being comprised of a plurality of segments including at least a first segment and a second segment, the first segment having a length “l1” and the second segment having a length “l2”, the method comprising the steps of:
assigning a first terrain cost “w1” to the first segment and a second terrain cost “w2” to the second segment, the first terrain cost expressing an impact upon at least one of a plurality of attributes of interest arising from incorporation of the first segment into the possible path and the second terrain cost expressing an impact upon the at least one of the plurality of attributes of interest arising from incorporation of the second segment into the possible path;
assigning a first shape cost “s1” to the first segment and a second shape “s2” cost to the second segment, the first shape cost expressing an intrinsic first segment impact upon the at least one of the plurality of attributes of interest arising from incorporation of the first segment into the possible path while articulating the first segment with a selected first one of a plurality of selected shapes and the second shape cost expressing an intrinsic second segment impact upon the at least one of the plurality of attributes of interest arising from incorporation of the second segment into the possible path while articulating the second segment with a selected second one of a plurality of selected shapes; and
incorporating the first terrain cost, the first shape cost, the length of the first segment, the second terrain cost, the second shape cost and the length of the second segment to generate a relative assessment of the impact the first and second segments upon the at least one of the plurality of attributes of interest.

31. A computer program for a routing system, the computer program comprising one or more computer readable medium having computer executable instructions which, when executed by one or more processors, implement the method of claim 30.

32. The method of claim 30 in which the selected first one of the plurality of selected shapes and the selected second one of the plurality of selected shapes are the same.

33. The method of claim 30 in which the step of incorporating the first terrain cost, the first shape cost, the length of the first segment, the second terrain cost, the second shape cost, and the length of the second segment to generate a relative assessment of the impact the first and second segments upon the at least one of the plurality of attributes of interest is performed in correspondence with the equation:
Σlᵢ (wᵢ+sᵢ).

34. A computer program for a routing system, the computer program comprising one or more computer readable medium having computer executable instructions which, when executed by one or more processors, implement the method of claim 33.

35. The method of claim 30 in which the step of incorporating the first terrain cost, the first shape cost, the length of the first segment, the second terrain cost, the second shape cost, and the length of the second segment to generate a relative assessment of the impact the first and second segments upon the at least one of the plurality of attributes of interest is performed in correspondence with the equation:
Σlᵢ(wᵢ)+lᵢ(sᵢ).

36. The method of claim 30 in which the step of incorporating the first terrain cost, the first shape cost, the length of the first segment, the second terrain cost, the second shape cost and the length of the second segment to generate a relative assessment of the impact the first and second segments upon the at least one of the plurality of attributes of interest is performed in correspondence with the equation:
Σ(wᵢ+sᵢ)+l_{i.}

37. A computer program for a routing system, the computer program comprising one or more computer readable medium having computer executable instructions which, when executed by one or more processors, implement the method of claim 36.

38. The method of claim 30 in which the step of incorporating the first terrain cost, the first shape cost, the length of the first segment, the second terrain cost, the second shape cost and the length of the second segment to generate a relative assessment of the impact the first and second segments upon the at least one of the plurality of attributes of interest is performed in correspondence with the equation:
Σ(wᵢ)+Σ(sᵢ)+Σlᵢ.

39. A method for evaluating a possible path in routing a connection in an integrated circuit, the possible path being comprised of a plurality of segments including at least a first segment and a second segment, the first segment having a length “l1” and the second segment having a length “l2”, the method comprising the steps of:
assigning a first terrain cost “w1” to the first segment and a second terrain cost “w2” to the second segment, the first terrain cost expressing an impact upon at least one of a plurality of attributes of interest arising from incorporation of the first segment into the possible path and the second terrain cost expressing an impact upon the at least one of the plurality of attributes of interest arising from incorporation of the second segment into the possible path; and
adding the sum of the first terrain cost and the second terrain cost with the sum of the length of the first segment and the length of the second segment to generate a relative assessment of the impact the first and second segments may have upon the at least one of the plurality of attributes of interest.

40. A computer program for a routing system, the computer program comprising one or more computer readable medium having computer executable instructions which, when executed by one or more processors, implement the method of claim 39.

41. A method of routing nets within an integrated circuit layout using a routing grid, the method comprising the steps of:
determining the presence of two routing blockages;
determining a number of gridlines between the two routing blockages;
determining an offset distance of the gridlines between the two routing blockages, the offset distance devised to increase the usability of space between the two routing blockages;
shifting the gridlines between the two routing blockages by the offset distance.

42. The method of claim 41 in which the offset distance is also devised to increase the number of gridlines that will fit between the two routing blockages.

43. The method of claim 41 in which the offset distance is also devised to increase the number of unblocked gridlines between the two routing blockages.

44. The method of claim 41 in which the step of determining an offset distance includes computing a difference between a first blockage distance associated with gridlines to a second actual distance between a selected edge gridline and a selected routing blockage.

45. A method of routing nets within an integrated circuit layout using a routing grid, the method comprising the steps of:
selecting a first area of the routing grid with a first designated number of required traces passing through the first area;
determining an optimal distance between respective pairs of the required traces;
applying a routing grid pitch change for the first area, the routing grid pitch change devised to allow placement of respective pairs of the required traces at the optimal distance;
routing the required traces on the routing grid having the routing grid pitch change applied.

46. A computer program for a routing system, the computer program comprising one or more computer readable medium having computer executable instructions which, when executed by one or more processors, implement the method of claim 45.

47. The method of claim 45 in which the first designated number of required traces is lower than a maximum number of that may be routed through the first area at an original grid pitch.

48. The method of claim 45 in which routing grid pitch change increases the pitch of the routing grid.

49. The method of claim 45 in which the first designated number of required traces is higher than a maximum number of that may be routed through the first area at an original grid pitch.

50. The method of claim 45 in which routing grid pitch change decreases the pitch of the routing grid.

51. The method of claim 45 in which the first designated number of required traces is lower than a maximum number of that may be routed through the first area, and, after the step of routing the required traces on the routing grid having the routing pitch change applied, the required traces are equally spaced.

52. A method of routing nets using processing elements that operate in parallel, the method comprising the steps:
designating two or more first processing period routing areas to be processed in parallel during a first processing period, the two or more first processing period routing areas not overlapping each other;
designating two or more second processing period routing areas to be processed in parallel during a second processing period, the two or more second processing period routing areas not overlapping each other, at least one of the second processing period routing areas overlapping one of the first processing period routing areas at an overlap area;
dividing one or more traces that need to be routed in two or more of the routing areas into two or more subtraces, each subtrace being within one respective routing area;
routing traces in the first processing period routing areas during a first processing period;
routing traces in the second processing period routing areas during a second processing period, the second processing period not overlapping the first processing period.

53. A computer program for a routing system, the computer program comprising one or more computer readable medium having computer executable instructions which, when executed by one or more processors, implement the method of claim 52.

54. The method of claim 52 in which the step of dividing one or more traces further comprises designating virtual pins at selected ends of the two or more subtraces.

55. The method of claim 54 in which at least one of the virtual pins is located in the overlap area.

56. The method of claim 55 further including the steps of:
performing global routing for a selected set of traces;
selecting virtual pin placement for selected traces based on the results of global routing.

57. The method of claim 52 further comprising the step of designating a routing grid over all of the routing areas.

58. The method of claim 52 in which the overlap area has a width of at least two grid squares.

59. The method of claim 52 in which the two or more first processing period routing areas are separated by a distance greater than a designated electrical effect distance.

60. The method of claim 52 further including the step of updating a master-wire storage database after each processing period with routes produced during the period.

61. A method of routing nets using processing elements that operate in parallel, the method comprising the steps:
designating one or more first areas of a layout region;
designating one or more second areas of the layout region, selected ones of the one or more second areas partially overlapping respective ones of the one or more first areas;
designating one or more third areas of the layout region, selected ones of the one or more third areas partially overlapping respective ones of the one or more second areas;
dividing traces that need to be routed in two or more of the areas into two or more subtraces, each subtrace being within one respective area;
designating a first processing cycle in which the first and third areas are processed by different processing elements;
designating a second processing cycle in which the second area is processed.

62. A computer program for a routing system, the computer program comprising one or more computer readable medium having computer executable instructions which, when executed by one or more processors, implement the method of claim 61.

63. The method of claim 61 in which the processing elements are microprocessors running in parallel.

64. The method of claim 61 in which the processing elements are microprocessor cores running in parallel.

65. A method of claim 64 in which two or more of the microprocessor cores are on a common integrated circuit.

66. A method of routing nets in an integrated circuit chip design using processing elements that operate in parallel, the method comprising the steps:
(a) dividing a routing area into a plurality of overlapping zones;
(b) processing routes within a selected, non-adjacent first set of the zones such that each processing element does not utilize design resources in interference with any other processing element;
(c) after step (b), processing routes within a selected, non-adjacent second set of the zones such that each processing element does not utilize design resources in interference with any other processing element.

67. A method of searching for net routes within an integrated circuit layout using a routing grid, the method comprising the steps of:
from a beginning gridpoint, determining what gridpoints are neighboring gridpoints;
determining which of the neighboring gridpoints are unblocked;
labeling the unblocked neighboring gridpoints with a wave number, the wave number comprising a first distance number and second cost number.

68. A computer program for a routing system, the computer program comprising one or more computer readable medium having computer executable instructions which, when executed by one or more processors, implement the method of claim 67.

69. The method of claim 67 further including the step of determining the cost number associated with each unblocked neighboring gridpoint, the cost number being derived at least partially from an electrical trace type of a selected net for which a route is being searched.

70. The method of claim 67 further including the step of determining the cost number associated with each unblocked neighboring gridpoint, the cost number being derived at least partially from a variable distance between gridpoints.

71. The method of claim 67 further including the step of determining the cost number associated with each unblocked neighboring gridpoint, the cost number being derived at least partially from electrical rules governing a portion of the routing grid being searched.

72. The method of claim 67 further including the step of determining the cost number associated with each unblocked neighboring gridpoint, the cost number being derived from a sum of associated cost metrics.

73. The method of claim 67 further including the step of determining the cost number associated with each unblocked neighboring gridpoint, the cost number being derived from a maximum of associated cost metrics.

74. A method of searching for net routes within an integrated circuit layout using a routing grid, the method comprising the steps of:
(a) from a point in a route, determining what gridpoints are neighboring gridpoints;
(b) determining what neighboring gridpoints are unblocked;
(c) in the same search wave as step (b), determining the length of any unblocked straight sequences of gridpoints from the point in the route;
(d) in the same search wave as step (b), labeling each gridpoint in any unblocked straight sequences of gridpoints for each unblocked neighboring gridpoint.

75. A computer program for a routing system, the computer program comprising one or more computer readable medium having computer executable instructions which, when executed by one or more processors, implement the method of claim 74.

76. The method of claim 74 further including the step of adding a minimum possible cost to reach a destination to a label value at each gridpoint.

77. A method of searching for net routes within an integrated circuit layout using a routing grid, the method comprising the steps of:
(a) from a point in a route, determining the presence of an unblocked area of the routing grid along a global routing path;
(b) applying a sparse routing grid over the unblocked area of routing grid, the sparse routing grid having a larger pitch than the routing grid;
(c) searching for a route on the sparse routing grid to complete a portion of the global routing path.

78. A computer program for a routing system, the computer program comprising one or more computer readable medium having computer executable instructions which, when executed by one or more processors, implement the method of claim 77.

79. The method of claim 77 in which the sparse routing grid has a pitch size that is an integer multiple of a pitch size of the routing grid.

80. The method of claim 77 in which the sparse routing grid is generated dynamically and deleted after routing a designated route.

81. The method of claim 77 in which the sparse routing grid is generated dynamically for a designated set of routes and deleted after routing the designated set of routes.
